(19) United States
(12) Patent Application Publication
(10) Pub. No.: US 2022/0148980 A1
(43) Pub. Date: May 12, 2022

(54) FILM FORMING APPARATUS, FILM FORMING METHOD, AND FILM FORMING SYSTEM

(71) Applicant: Tokyo Electron Limited, Minato-ku, Tokyo (JP)

(72) Inventors: Atsushi KUBO, Minato-ku, Tokyo (JP); Takayuki YAMAGISHI, Fuchu-shi, Tokyo (JP); Takayuki KAMAISHI, Nirasaki-shi, Yamanishi (JP); Tetsuya SAITO, Nirasaki-shi, Yamanashi (JP)

(21) Appl. No.: 17/594,224

(22) PCT Filed: Mar. 25, 2020
(86) PCT No.: PCT/JP2020/013312

§ 371 Date: Oct. 7, 2021

(30) Foreign Application Priority Data
Apr. 8, 2019 (JP) 2019-073779

(51) Int. Cl. H01L 23/00; H01L 21/56; C23C 16/50; C23C 16/52; C23C 16/458

(52) U.S. Cl. CPC H01L 23/562; H01L 21/56; C23C 16/4583; C23C 16/52; C23C 16/50

(57) ABSTRACT

A film forming apparatus includes: a processing container; a stage arranged inside the processing container and configured to place a substrate thereon, the stage including a plurality of film forming portions configured to form a film on a back surface of the substrate opposite to a surface of the substrate on which an element is formed, with a material gas supplied to the back surface via a supply port having a shape forming at least a portion of a film forming pattern for reducing stress applied to the substrate; and a control device configured to independently control film formations on the back surface by the plurality of film forming portions.

### TECHNICAL FIELD

Various aspects and embodiments of the present disclosure relate to a film forming apparatus, a film forming method, and a film forming system.

### BACKGROUND

In a process of manufacturing a semiconductor device, various elements are formed on a substrate. The elements are formed by forming films made of a plurality of different materials on the substrate, and etching the materials of the films thus formed. Since the linear expansion coefficient differs between the substrate and the material forming a film on the substrate, when the temperature of the substrate returns to the room temperature after film formation, stress may be generated on the substrate, and warpage or cracks may occur. Therefore, in order to reduce the stress applied to the substrate after the elements are formed, there is known a technique of forming a film on the back surface opposite to the surface on which the elements are formed (see, e.g., Patent Document 1 below).

### PRIOR ART DOCUMENTS

### Patent Documents

Patent Document 1: U.S. Patent Application Publication No. 2015/0340225

### SUMMARY

The present disclosure provides some embodiments of a film forming apparatus, a film forming method, and a film forming system, which are capable of reducing the man-hours required for film formation to reduce the warpage of a substrate.

One aspect of the present disclosure provides a film forming apparatus including a processing container, a stage and a control device. The stage is arranged inside the processing container so that a substrate is mounted on the stage. The stage includes a plurality of film forming portions configured to form a film on a back surface of the substrate opposite to a surface of the substrate on which an element is formed, by supplying a material gas to the back surface via a supply port having a shape forming at least a portion of the film forming pattern for reducing stress applied to the substrate. The control device independently controls film formations on the back surface of the substrate by the film forming portions.

According to various aspects and embodiments of the present disclosure, it is possible to reduce the man-hours required for film formation to reduce the warpage of a substrate.

### BRIEF DESCRIPTION OF DRAWINGS

FIG. 1 is a system configuration diagram showing an example of a semiconductor manufacturing system according to an embodiment of the present disclosure.

FIG. 2 is a schematic sectional view showing an example of a second film forming apparatus according to an embodiment of the present disclosure.

FIG. 3 is a top view showing an example of a stage according to an embodiment of the present disclosure.

FIG. 4 is an enlarged sectional view showing an example of a film forming portion.

FIG. 5 is a schematic diagram showing an example of a gas flow in a diffusion chamber.

FIGS. 6A and 6B are diagrams showing examples of a pattern of a film formed on a back surface of a wafer.

FIG. 7 is a schematic sectional view showing another example of the second film forming apparatus.

FIG. 8 is a top view showing another example of the stage.

FIG. 9 is an enlarged sectional view showing another example of the film forming portion.

FIG. 10 is a schematic sectional view showing another example of the second film forming apparatus.

### DETAILED DESCRIPTION

Hereinafter, embodiments of a film forming apparatus, a film forming method and a film forming system disclosed herein will be described in detail with reference to the drawings. It should be noted that the following embodiments do not limit the film forming apparatus, the film forming method and the film forming system disclosed herein.

By the way, elements are formed by etching a material forming a film on a substrate into various shapes. Therefore, the stress applied to the substrate after the elements are formed has a complicated distribution on the substrate. As a result, the pattern of a film to be formed on the back surface of the substrate in order to cancel the stress having a complicated distribution also becomes complicated.

When a film having a complicated pattern is formed on the back surface of a substrate, for example, a mask material is formed as a film on the back surface of the substrate, and a pattern for canceling stress is formed on the formed mask by photolithography or the like. Then, a film having a shape corresponding to the mask pattern is formed on the back surface of the substrate.

Further, in order to prevent damage or deterioration of the elements formed on the substrate, it is necessary to perform a step of laminating a protective film for protection of the elements on the surface of the substrate on which the elements are formed, and a step of removing the protective film after the film formation on the back surface is completed. In this way, a plurality of steps is required to form a film having a predetermined pattern on the back surface. Therefore, the throughput in the manufacture of a semiconductor device using the substrate is lowered.

Therefore, the present disclosure provides a technique capable of reducing the man-hours required for film formation to reduce the warpage of the substrate.

### [Semiconductor Manufacturing System]

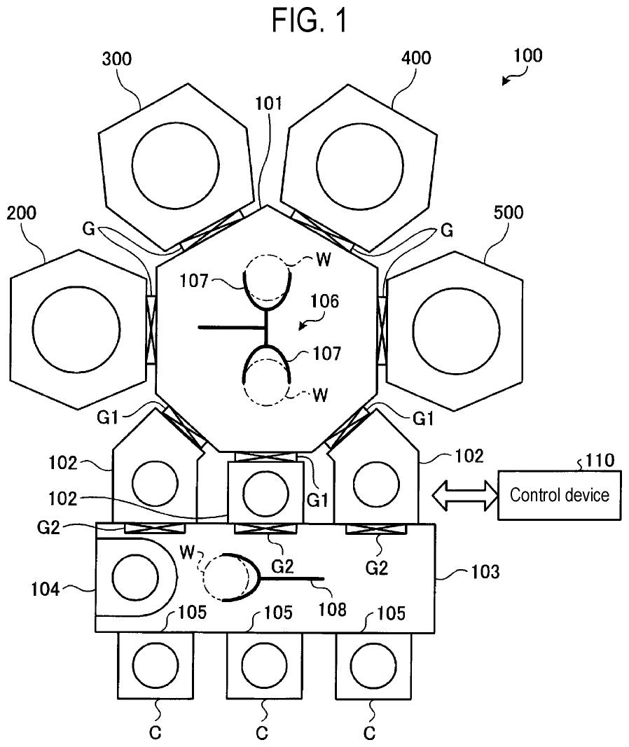

FIG. 1 is a system configuration diagram showing an example of a semiconductor manufacturing system 100 according to an embodiment of the present disclosure. The semiconductor manufacturing system 100 includes a first film forming apparatus 200, an etching apparatus 300, a measuring device 400, and a second film forming apparatus 500. These apparatuses are connected to four side walls of a vacuum-side transfer chamber 101 having a heptagonal planar shape via gate valves G, respectively. The semiconductor manufacturing system 100 is a multi-chamber type vacuum processing system. The inside of the vacuum-side transfer chamber 101 is evacuated by a vacuum pump and is maintained at a predetermined degree of vacuum. The semiconductor manufacturing system 100 is an example of a film forming system.

The first film forming apparatus 200 forms a conductive film, an insulating film or the like on a substantially disk-shaped wafer W, which is an example of a substrate. The etching apparatus 300 etches the conductive film or the like formed on the wafer W by the first film forming apparatus 200 into a predetermined pattern by dry etching or the like. By repeating the film formation by the first film forming apparatus 200 and the etching by the etching apparatus 300, an element used as a semiconductor device is formed on the wafer W.

The measuring device 400 measures a height distribution of the wafer W on which the element is formed, and outputs a measurement result to a control device 110. The height distribution of the wafer W can be measured by using a measuring instrument such as a laser beam displacement meter or the like. For example, the wafer W on which the element is formed is placed on a stage in the measuring device 400. A laser beam displacement meter arranged on the ceiling of the measuring device 400 irradiates the surface of the wafer W on which the element is formed with a laser beam while moving horizontally above the wafer W placed on the stage.

Local distortion and warpage occur in the wafer W depending on the shape and thickness distribution of the film formed on the wafer W. The laser beam displacement meter can measure the height of the wafer W by measuring the reflected light reflected by the wafer W. The measured height distribution corresponds to information indicating the distortion and warpage of the wafer W.

The control device 110 calculates a film forming pattern formed on the back surface opposite to the surface of the wafer W on which the element is formed (hereinafter simply referred to as “back surface”) and used for reducing distortion and warpage occurring in the wafer W, based on the measurement results measured by the measuring device 400. Then, the control device 110 specifies a film forming pattern close to the calculated film forming pattern from a number of predetermined film forming patterns.

The second film forming apparatus 500 forms a predetermined film on the back surface of the wafer W according to the film forming pattern specified by the control device 110. As a result, the stress generated on the wafer W by the element formed on one surface of the wafer W is reduced, and the distortion and warpage of the wafer W are reduced.

Three load lock chambers 102 are connected to the remaining three side walls of the vacuum-side transfer chamber 101 via respective gate valves G1. An atmospheric-side transfer chamber 103 is provided on the opposite side of the load lock chambers 102 from the vacuum-side transfer chamber 101. Each of the three load lock chambers 102 is connected to the atmospheric-side transfer chamber 103 via respective gate valves G2. The load lock chambers 102 control the pressure between the atmospheric pressure and the vacuum when the wafer W is transferred between the atmospheric-side transfer chamber 103 and the vacuum-side transfer chamber 101.

On the side surface of the atmospheric-side transfer chamber 103 opposite to the side surface on which the gate valves G2 are provided, there are provided three ports 105 for attaching carriers (FOUPs (Front-Opening Unified Pods) C for accommodating the wafer W. Further, an alignment chamber 104 for aligning the wafer W is provided on the side wall of the atmospheric-side transfer chamber 103. A down-flow of a clean air is formed inside the atmospheric-side transfer chamber 103.

A transfer mechanism 106 such as a robot arm or the like is provided inside the vacuum-side transfer chamber 101. The transfer mechanism 106 transfers the wafer W between the first film forming apparatus 200, the etching apparatus 300, the measuring device 400, the second film forming apparatus 500 and the respective load lock chambers 102. The transfer mechanism 106 includes two arms 107 that can move independently.

A transfer mechanism 108 such as a robot arm or the like is provided inside the atmospheric-side transfer chamber 103. The transfer mechanism 108 transfers the wafer W between the respective carriers C, the respective load lock chambers 102 and the alignment chamber 104.

The semiconductor manufacturing system 100 includes the control device 110 including a memory, a processor and an input/output interface. The memory stores a program executed by the processor and a recipe including conditions for each process. The processor executes a program read from the memory and controls each part of the semiconductor manufacturing system 100 via the input/output interface based on the recipe stored in the memory. The control device 110 is an example of a specifying device.

### [Details of the Second Film Forming Apparatus 500]

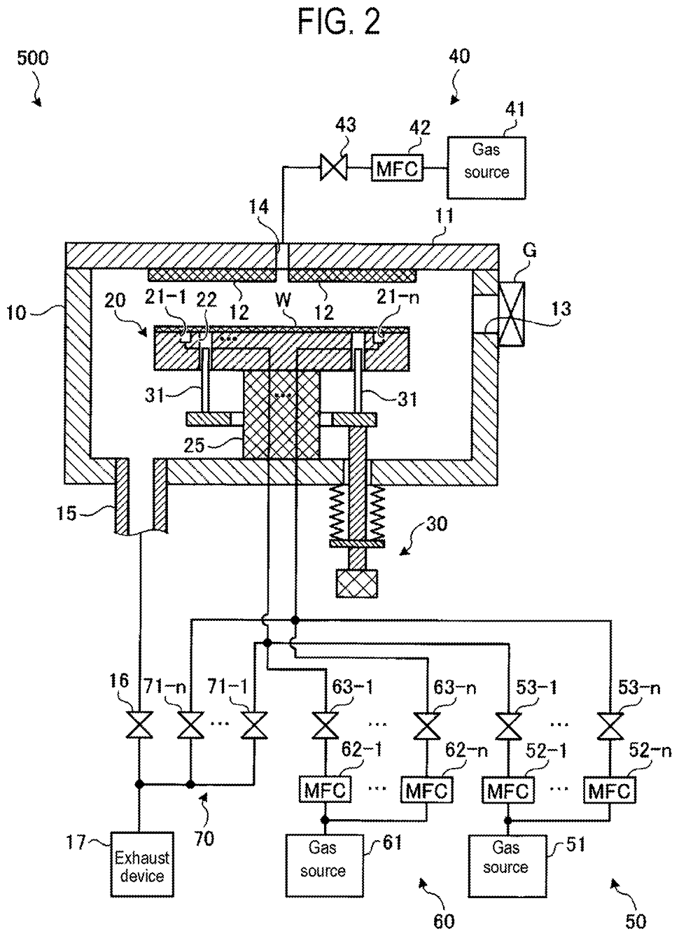

FIG. 2 is a schematic sectional view showing an example of the second film forming apparatus 500 according to an embodiment of the present disclosure. The second film forming apparatus 500 includes a bottomed tubular processing container 10 having an internal space formed therein. An upper portion of the processing container 10 is covered by a lid 11. An opening 13 is provided on a side wall of the processing container 10, and the opening 13 is opened and closed by a gate valve G.

One end of an exhaust pipe 15 is connected to the bottom portion of the processing container 10. The other end of the exhaust pipe 15 is connected to the exhaust device 17 via an APC (Automatic Pressure Controller) valve 16. By driving the exhaust device 17, the gas in the processing container 10 is exhausted through the exhaust pipe 15. By adjusting an opening degree of the APC valve 16, an internal pressure of the processing container 10 is regulated.

A stage 20 on which the wafer W is placed is provided inside the processing container 10. The stage 20 is supported by a support portion 25. The support portion 25 is supported by the bottom portion of the processing container 10. The stage 20 has a plurality of film forming portions 21-1 to 21-n (where n is an integer of 2 or more). In the following, the respective film forming portions 21-1 to 21-n may be collectively referred to as film forming portions 21 without being distinguished from one another. The film forming portions 21 form a film forming pattern specified by the control device 110 on the back surface of the wafer W which is placed on the stage 20 so that the surface on which the element is formed is oriented upward.

Further, the stage 20 has a plurality of through-holes 22 through which a plurality of support pins 31 penetrates. The respective support pins 31 are moved up and down by an elevating mechanism 30. For example, when the wafer W is loaded into the processing container 10 by the arm 107, the elevating mechanism 30 moves the support pins 31 upward. As a result, the wafer W is delivered to the support pins 31. Then, the wafer W is placed on the stage 20 by moving the support pins 31 downward by the elevating mechanism 30. Further, when the wafer W is to be unloaded from the processing container 10, the elevating mechanism 30 lifts the wafer W by moving the support pins 31 upward. Then, the arm 107 is inserted below the wafer W. As the elevating mechanism 30 moves the support pins 31 downward, the wafer W is delivered to the arm 107. Then, the wafer W is unloaded from the processing container 10 by the arm 107.

A heater 12 for controlling the temperature of the wafer W placed on the stage 20 is provided on a lower surface of the lid 11. The heater 12 controls the temperature of the wafer W placed on the stage 20 by radiant heat to a temperature suitable for film formation. The heater 12 may be another heating mechanism such as a lamp or the like. The heater 12 is an example of a temperature control part.

A first gas supply mechanism 50, a second gas supply mechanism 60 and a valve group 70 are connected to each of the film forming portions 21. The first gas supply mechanism 50 includes a gas source 51, a plurality of MFCs (Mass Flow Controllers) 52-1 to 52-n, and a plurality of valves 53-1 to 53-n. In the following, the respective MFC52-1 to 52-n may be collectively referred to as MFCs52 without being distinguished from one another, and the respective valves 53-1 to 53-n may be collectively referred to as valves 53 without being distinguished from one another.

One MFC 52 and one valve 53 are provided for one film forming portion 21. One end of each valve 53 is connected to the corresponding film forming portion 21 via a pipe. The other end of each valve 53 is connected to the gas source 51, which is a first gas source, via the corresponding MFC 52. Each MFC 52 controls a flow rate of a first gas supplied from the gas source 51, and supplies the flow-rate-controlled first gas to the corresponding film forming portion 21 via the corresponding valve 53. The respective MFCs 52 and the respective valves 53 are controlled independently of each other by the control device 110.

The second gas supply mechanism 60 includes a gas source 61, a plurality of MFCs 62-1 to 62-n, and a plurality of valves 63-1 to 63-n. In the following, the respective MFCs 62-1 to 62-n may be collectively referred to as MFCs 62 without being distinguished from one another, and the respective valves 63-1 to 63-n may be collectively referred to as valves 63 without being distinguished from one another.

One MFC 62 and one valve 63 are provided for one film forming portion 21. One end of each valve 63 is connected to the corresponding film forming portion 21 via a pipe. The other end of each valve 63 is connected to the gas source 61, which is a second gas source, via the corresponding MFC 62. Each MFC 62 controls a flow rate of a second gas supplied from the gas source 61, and supplies the flow-rate-controlled second gas to the corresponding film forming portion 21 via the corresponding valve 63. The respective MFCs 62 and the respective valves 63 are controlled independently of each other by the control device 110. The first gas and the second gas are examples of material gases.

The valve group 70 includes a plurality of valves 71-1 to 71-n. In the following, the respective valves 71-1 to 71-n may be collectively referred to as valves 71 without being distinguished from one another. One valve 71 is provided for one film forming portion 21. One end of each valve 71 is connected to the corresponding film forming portion 21 via a pipe. Further, the other end of each valve 71 is connected to the exhaust device 17. The respective valves 71 are controlled independently of each other by the control device 110.

The lid 11 has a gas introduction port 14 for supplying a purge gas into the processing container 10 therethrough. A purge gas supply mechanism 40 is connected to the gas introduction port 14 via a pipe. The purge gas supply mechanism 40 includes a gas source 41, an MFC 42, and a valve 43. One end of the valve 43 is connected to the gas introduction port 14 via a pipe. The other end of the valve 43 is connected to the gas source 41, which is a purge gas source, via the MFC 42. The purge gas is an inert gas such as a helium gas, an argon gas, or a nitrogen gas.

The MFC 42 controls a flow rate of the purge gas supplied from the gas source 41 at the time of film formation on the back surface of the wafer W, and supplies the flow-rate-controlled purge gas into the processing container 10 via the valve 43 and the gas introduction port 14. The gas introduction port 14 supplies the purge gas to the surface of the wafer W on which the element is formed, while the wafer W is placed on the stage 20. The gas introduction port 14 is an example of a purge gas supply port. As a result, when the film is formed on the back surface of the wafer W, the gas used for forming the film on the back surface of the wafer W, the particles generated during the film formation on the back surface of the wafer W, and the like are prevented from moving toward the upper surface of the wafer W.

### [Details of Stage 20]

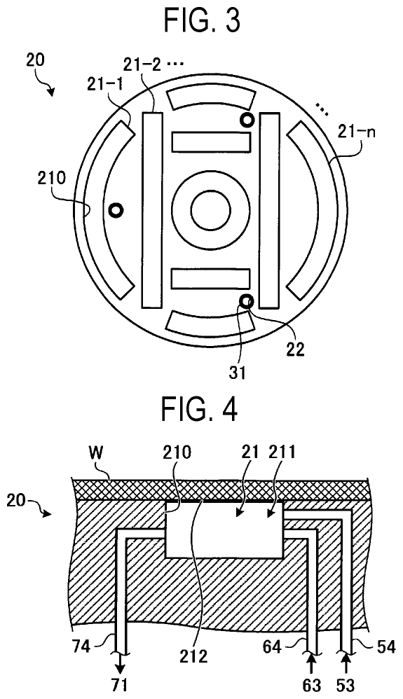

FIG. 3 is a top view showing an example of the stage 20 according to an embodiment of the present disclosure. As shown in FIG. 3, for example, a plurality of film forming portions 21 is provided on the upper surface of the stage 20. The respective film forming portions 21 form a film on the back surface of the wafer W opposite to the surface on which the element is formed, in a region having a shape forming at least a portion of the film forming pattern for reducing stress applied to the wafer W. The respective film forming portions 21 are arranged at different positions on the surface of the stage 20 on which the wafer W is placed. The supply port 210 of each film forming portion 21 is formed in a shape forming at least a portion of the film forming pattern for reducing the stress applied to the wafer W.

FIG. 4 is an enlarged sectional view showing an example of the film forming portion 21. FIG. 4 illustrates an example of the cross section of the film forming portion 21 in a state in which the wafer W is placed on the stage 20. Each film forming portion 21 has a diffusion chamber 211. A pipe 54, a pipe 64 and a pipe 74 are connected to the diffusion chamber 211. The first gas is supplied into the diffusion chamber 211 through the pipe 54, and the second gas is supplied into the diffusion chamber 211 through the pipe 64. The pipe 54 and the pipe 64 are examples of supply paths. A film 212 having a shape corresponding to the shape of the supply port 210 is formed in a region on the back surface of the wafer W corresponding to the supply port 210 by the first gas and the second gas supplied into the diffusion chamber 211.

In the present embodiment, the film 212 is formed in the region on the back surface of the wafer W surrounded by the supply port 210 by the first gas and the second gas supplied to the diffusion chamber 211. Therefore, the consumption of the first gas and the second gas can be reduced as compared with the case where a predetermined pattern film is formed on the back surface of the wafer W by etching the film formed on the entire back surface of the wafer W.

Further, the gas in the diffusion chamber 211 is exhausted through the pipe 74. The pipe 74 is an example of an exhaust path. A valve 71 is connected to the pipe 74, and an internal pressure of the diffusion chamber 211 is regulated by adjusting an opening degree of the valve 71. The opening degree of the valve 71 is controlled by the control device 110. The control device 110 controls the opening degree of the valve 71 so that an internal pressure of the diffusion chamber 211 is lower than the internal pressure of the processing container 10. As a result, the lower surface of the wafer W and the upper surface of the stage 20 on which the supply port 210 is not formed are brought into close contact with each other, and the gas supplied into the diffusion chamber 211 is suppressed from leaking to the outside of the diffusion chamber 211. The valve 71 is an example of a pressure control part.

The inside of the diffusion chamber 211 may also be evacuated in the film forming portion 21 that is not included in the film forming pattern region specified by the control device 110. As a result, it is possible to enhance the adhesion between the lower surface of the wafer W and the upper surface of the stage 20 on which the supply port 210 is not formed.

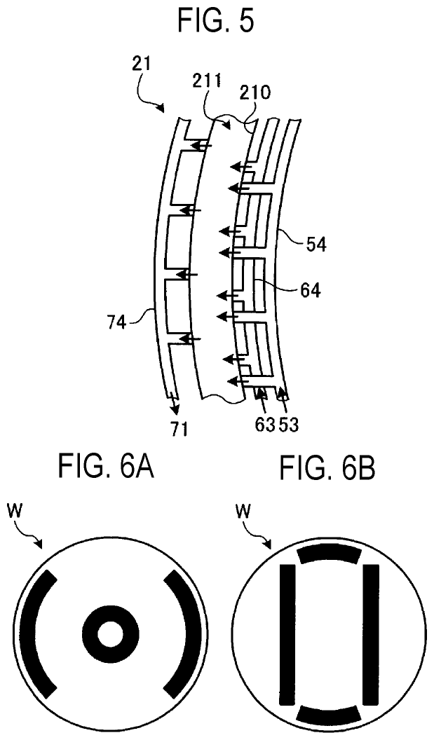

FIG. 5 is a schematic diagram showing an example of a gas flow in the diffusion chamber 211. In the diffusion chamber 211 having an elongated shape, for example, as shown in FIG. 5, it is preferable that the first gas and the second gas are supplied from a plurality of different positions on the side wall extending along the extension direction of the diffusion chamber 211. Further, for example, as shown in FIG. 5, the gas in the diffusion chamber 211 is preferably exhausted from a plurality of different positions on the side wall facing the side wall to which the first gas and the second gas are supplied. As a result, it is possible to suppress unevenness in the thickness of the film formed in the region on the back surface of the wafer W corresponding to the supply port 210.

By supplying the material gas to the back surface of the wafer W from the film forming portion 21 corresponding to the film forming pattern specified by the control device 110, for example, as shown in FIGS. 6A and 6B, a film having a film forming pattern specified by the control device 110 is formed on the back surface of the wafer W. FIGS. 6A and 6B are diagrams showing examples of the pattern of the film formed on the back surface of the wafer W. In FIGS. 6A and 6B, regions indicated by solid black images are regions on the back surface of the wafer W on which the film is formed.

After the film is formed on the back surface of the wafer W, the wafer W may be unloaded from the processing container 10, the orientation of the wafer W may be changed by an external device of the second film forming apparatus 500, then the wafer W may be returned to the processing container 10, and a film may be formed again on the back surface of the wafer W. By repeating the film formation on the back surface of the wafer W and the change of the orientation of the wafer W, a film forming pattern having a higher degree of freedom can be formed on the back surface of the wafer W.

One embodiment has been described above. As described above, the semiconductor manufacturing system 100 according to the present embodiment includes the measuring device 400, the control device 110, and the second film forming apparatus 500. The measuring device 400 measures the height distribution of the wafer W. The control device 110 specifies a film forming pattern for reducing the stress applied to the wafer W based on the height distribution measured by the measuring device 400. The second film forming apparatus 500 forms a film on the back surface of the wafer W opposite to the surface on which the element is formed, according to the film forming pattern specified by the control device 110. The second film forming apparatus 500 includes the processing container 10 and the stage 20. The stage 20 is arranged inside the processing container 10 so that the wafer W is placed thereon. Further, the stage 20 includes the plurality of film forming portions 21 for forming a film on the back surface of the wafer W by supplying the material gas to the back surface of the wafer W opposite to the surface on which the element is formed, via the supply port 210 having a shape forming at least a portion of the film forming pattern for reducing the stress applied to the wafer W. The control device 110 independently controls the film formations on the back surface of the wafer W by the respective film forming portions 21. As a result, it is possible to reduce the man-hours required for film formation to reduce the warpage of the wafer W.

Further, in the above-described embodiment, each film forming portion 21 includes the diffusion chamber 211, the pipe 54, the pipe 64, and the pipe 74. The diffusion chamber 211 diffuses the material gas supplied to the back surface of the wafer W through the supply port 210. The pipe 54 and the pipe 64 supply the material gas into the diffusion chamber 211. The pipe 74 exhausts the gas in the diffusion chamber 211. The pipe 74 is provided with the valve 71 for controlling the internal pressure of the diffusion chamber 211. By controlling the valve 71, the control device 110 controls the internal pressure of the diffusion chamber 211 to be lower than the internal pressure of the processing container 10. As a result, the gas supplied into the diffusion chamber 211 can be suppressed from leaking to the outside of the diffusion chamber 211, and the film having a shape corresponding to the shape of the supply port 210 can be formed on the back surface of the wafer W.

Further, in the above-described embodiment, the second film forming apparatus 500 includes the gas introduction port 14 that supplies the purge gas to the surface of the wafer W placed on the stage 20 on which the element is formed. As a result, when the film is formed on the back surface of the wafer W, the gas used for forming the film on the back surface of the wafer W, the particles generated during the film formation on the back surface of the wafer W, and the like are prevented from moving toward the upper surface of the wafer W.

### [Others]

The technique disclosed herein is not limited to the above-described embodiments, and may be modified in various forms within the scope of the gist thereof.

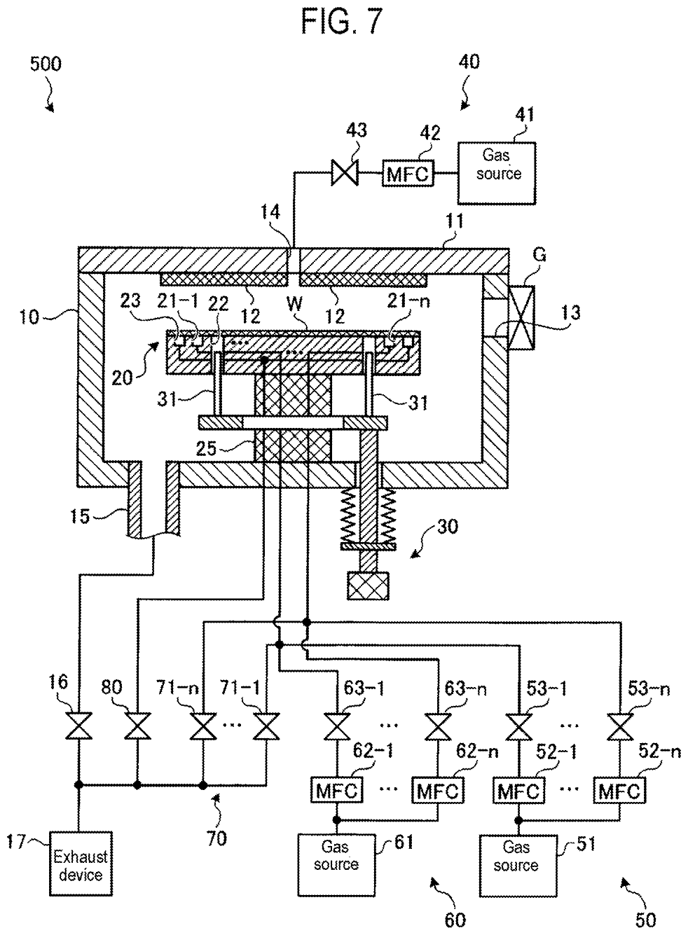

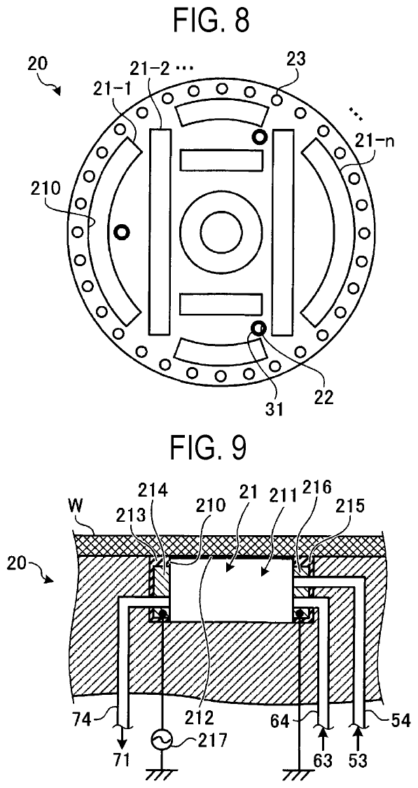

For example, in another embodiment, the stage 20 may have a suction port 23 for sucking the gas existing between the wafer W placed on the stage 20 and the stage 20 as shown in FIGS. 7 and 8. FIG. 7 is a schematic sectional view showing another example of the second film forming apparatus 500. FIG. 8 is a top view showing another example of the stage 20.

A plurality of suction ports 23 is provided on the upper surface of the stage 20. Each suction port 23 is connected to the exhaust device 17 via a valve 80. When the valve 80 is opened with the wafer W placed on the stage 20, the gas existing between the wafer W and the stage 20 is sucked so that the lower surface of the wafer W and the upper surface of the stage 20 are in close contact with each other. As a result, the gas supplied into the diffusion chamber 211 is more effectively suppressed from leaking to the outside of the diffusion chamber 211.

In the examples of FIGS. 7 and 8, the suction of the gas from the plurality of suction ports 23 implements close contact between the lower surface of the wafer W and the upper surface of the stage 20, whereby leakage of the gas existing in the diffusion chamber 211 can be suppress without significantly reducing the internal pressure of the chamber 211 of each film-forming portion 21. Therefore, the flow rates of the first gas and the second gas can be increased, and the time required for film formation on the back surface of the wafer W can be shortened.

Further, in the example of FIG. 8, the plurality of suction ports 23 is provided in a region of the upper surface of the stage 20 on the more outer peripheral side than the region where the plurality of film forming portions 21 is arranged. Thus, even if the gas is leaked from each diffusion chamber 211, the leaked gas is exhausted from the suction port 23. As a result, it is possible to prevent the gas leaked from the diffusion chamber 211 from entering the side of the upper surface of the wafer W when the film is formed on the back surface of the wafer W. In the example of FIG. 8, the shape of each suction port 23 is substantially circular. As another example, the shape of each suction port 23 may be an elongated shape along the outer periphery of the upper surface of the stage 20.

Further, in the above-described embodiment, the film having a predetermined pattern is formed on the back surface of the wafer W by supplying the material gas to the back surface of the wafer W. However, the disclosed technique is not limited thereto. For example, the material gas may be formed into plasma, and a film having a predetermined pattern may be formed on the back surface of the wafer W by using active species contained in the plasma.

FIG. 9 is an enlarged sectional view showing another example of the film forming portion 21. In the example of FIG. 9, an electrode 214 is arranged on one of the side walls facing each other inside the diffusion chamber 211 with an insulating member 213 interposed therebetween. An electrode 216 is provided on the other side wall with an insulating member 215 interposed therebetween. The electrode 214 and the electrode 216 are formed in a plate shape and are arranged along the side walls of the diffusion chamber 211 so as to face each other. A radio-frequency power source 217 is electrically connected to the electrode 214, and the electrode 216 is grounded. By supplying the radio-frequency power from the radio-frequency power source 217 to the electrode 214, the gas flowing in the diffusion chamber 211 is formed into plasma, and active species contained in the plasma are supplied to the back surface of the wafer W. Then, a predetermined film is formed on the back surface of the wafer W by the active species contained in the plasma. The electrode 214, the electrode 216 and the radio-frequency power source 217 are an example of a plasma generation part.

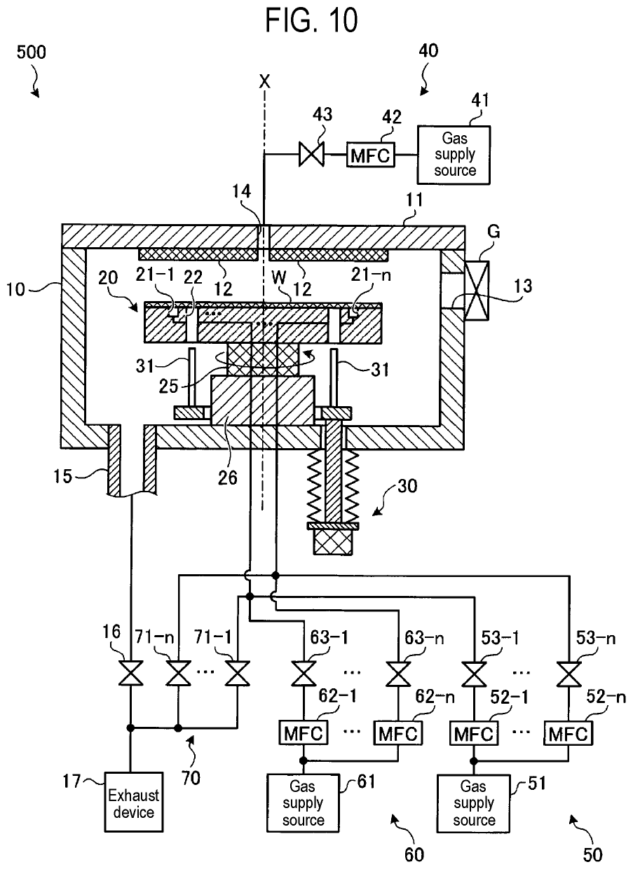

Further, in the above-described embodiment, the stage 20 is fixed to the bottom portion of the processing container 10 via the support portion 25. However, the disclosed technique is not limited thereto. For example, as shown in FIG. 10, the stage 20 may be rotated about the support portion 25 as an axis. FIG. 10 is a schematic sectional view showing another example of the second film forming apparatus 500.

In the example of FIG. 10, the support portion 25 that supports the stage 20 is supported by a drive part 26. The drive part 26 rotates the drive part 26. The drive part 26 rotates the support portion 25, for example, about a central axis X of the upper surface of the stage 20 having a substantially circular shape. As the support portion 25 rotates, the stage 20 supported by the support portion 25 also rotates about the axis X. The drive part 26 is an example of a rotation mechanism.

For example, after the film having a predetermined pattern is formed on the back surface of the wafer W, the wafer W is delivered to the arm 107 by the support pins 31. Then, after the support pins 31 are retracted, the drive part 26 rotates the stage 20 by a predetermined angle about the axis X. Then, the support pins 31 are moved upward, the wafer W is delivered from the arm 107 to the support pins 31, and the support pins 31 are retracted. As a result, the wafer W is placed on the upper surface of the stage 20 again in a state in which the stage 20 is rotated by the predetermined angle with respect to the wafer W. Then, a film having a predetermined pattern is formed again on the back surface of the wafer W. By repeating the film formation on the back surface of the wafer W and the rotation of the stage 20 with respect to the wafer W, a film forming pattern having a higher degree of freedom can be formed on the back surface of the wafer W.

Further, in the above-described embodiment, the measuring device 400 measures the height distribution of the wafer W after the element is formed, and the control device 110 specifies a film forming pattern based on the measurement result. However, the disclosed technique is not limited thereto. For example, if it is possible to estimate in advance the distortion and warpage of the wafer W when a predetermined element is formed on the wafer W, the height distribution of the wafer W after the element is formed does not have to be measured. In this case, a film forming pattern corresponding to the estimated height distribution is formed on the back surface of the wafer W without measuring the height distribution.

Further, in the above-described embodiment, a predetermined film forming pattern is formed on the back surface of the wafer W after the element is formed. However, the disclosed technique is not limited thereto. For example, if it is possible to estimate in advance the distortion and warpage of the wafer W when a predetermined element is formed on the wafer W, a film forming pattern corresponding to the estimated height distribution of the wafer W may be formed in advance on the back surface of the wafer W before the element is formed on the wafer W.

Further, in the above-described embodiment, the heater 12 is provided above the stage 20, and the wafer W is heated starting from the surface of the wafer W on which the element is formed. However, the disclosed technique is not limited thereto. For example, a temperature control member such as a heater or the like may be embedded in the stage 20, and the temperature of the wafer W may be controlled by the temperature control member embedded in the stage 20.

It should be noted that the embodiments disclosed herein are exemplary in all respects and are not limitative. Indeed, the above embodiments may be embodied in a variety of forms. Further, the above-described embodiments may be omitted, replaced or changed in various forms without departing from the scope of the appended claims and the spirit thereof.

### EXPLANATION OF REFERENCE NUMERALS

W: wafer, 100: semiconductor manufacturing system, 110: control device, 500: second film forming apparatus, 10: processing container, 11: lid, 12: heater, 14: gas introduction port, 20: stage, 21: film forming portion, 210: supply port, 211: diffusion chamber, 214: electrode, 216: electrode, 217: radio-frequency power source, 23: suction port, 26: drive part, 40: purge gas supply mechanism, 50: first gas supply mechanism, 60: second gas supply mechanism, 70: valve group, 71: valve, 80: valve

1. A film forming apparatus comprising:
a processing container;
a stage arranged inside the processing container and configured to place a substrate on the stage, the stage including a plurality of film forming portions configured to form a film on a back surface of the substrate opposite to a surface of the substrate on which an element is formed, with a material gas supplied to the back surface via a supply port having a shape forming at least a portion of a film forming pattern for reducing stress applied to the substrate; and
a control device configured to independently control film formations on the back surface by the plurality of film forming portions.

2. The film forming apparatus of claim 1, wherein each of the plurality of film forming portions includes a diffusion chamber configured to diffuse the material gas supplied to the back surface through the supply port, a supply path configured to supply the material gas into the diffusion chamber therethrough, and an exhaust path configured to exhaust a gas in the diffusion chamber therethrough,
a pressure control part configured to control an internal pressure of the diffusion chamber is provided in the exhaust path, and
the control device controls the pressure control part to control the internal pressure of the diffusion chamber to be lower than an internal pressure of the processing container.

3. The film forming apparatus of claim 2, wherein each of the plurality of film forming portions includes a plasma generation part configured to form the material gas supplied to the diffusion chamber into plasma, and
active species contained in the plasma generated by the plasma generation part are supplied to the back surface of the substrate from the supply port of each of the plurality of film forming portions.

4. The film forming apparatus of claim 1, wherein the stage includes a suction port configured to suck a gas existing between the substrate placed on the stage and the stage.

5. The film forming apparatus of claim 1, wherein the stage includes a temperature control member configured to control a temperature of the substrate placed on the stage.

6. The film forming apparatus of claim 1, wherein a surface of the stage on which the substrate is placed has a substantially circular shape,
the film forming apparatus further comprising:
a rotation mechanism configured to rotate the stage about a central axis of the surface of the stage.

7. The film forming apparatus of claim 1, further comprising:
a purge gas supply port configured to supply a purge gas to the surface of the substrate placed on the stage and on which the element is formed.

8. A film forming method, comprising:
placing a substrate on a stage provided inside a processing container; and
forming a film on a back surface of the substrate opposite to a surface of the substrate on which an element is formed, by independently controlling a plurality of film forming portions that forms a film on the back surface with a material gas supplied to the back surface via a supply port having a shape forming at least a portion of a film forming pattern for reducing stress applied to the substrate.

9. A film forming system, comprising:
a measuring device configured to measure a height distribution of a substrate;
a specifying device configured to specify a film forming pattern for reducing stress applied to the substrate, based on the height distribution measured by the measuring device; and
a film forming apparatus configured to form a film on a back surface of the substrate opposite to a surface of the substrate on which an element is formed, according to the film forming pattern specified by the specifying device,
wherein the film forming apparatus includes:
a processing container;
a stage arranged inside the processing container and configured to place a substrate on the stage, the stage including a plurality of film forming portions configured to form a film on a back surface of the substrate opposite to a surface of the substrate on which an element is formed, with a material gas supplied to the back surface via a supply port having a shape forming at least a portion of a film forming pattern for reducing stress applied to the substrate; and
a control device configured to independently control the plurality of film-forming portions to form the film on the back surface of the substrate according to the film forming pattern specified by the specifying device.
